(19) United States
(12) Patent Application Publication
(10) Pub. No.: US 2023/0051478 A1
(43) Pub. Date: Feb. 16, 2023

(54) GRAVURE PRINTING PLATE

(71) Applicant: UACJ FOIL CORPORATION, Tokyo (JP)

(72) Inventors: Tomoshige HASHIMURA, Tokyo (JP); Shiho WAKASONE, Tokyo (JP)

(21) Appl. No.: 17/788,938

(22) PCT Filed: Dec. 24, 2020
(86) PCT No.: PCT/JP2020/048602

§ 371 Date: Jun. 24, 2022

(30) Foreign Application Priority Data
Dec. 25, 2019 (JP) 2019-235319

(51) Int. Cl. B41N 1/06; B41F 13/187; H05K 3/12

(52) U.S. Cl. CPC B41N 1/06; B41F 13/187; H05K 3/12

(57) ABSTRACT

A gravure printing plate capable of printing straight image lines with high accuracy. The gravure printing plate is a gravure printing plate for printing an image line including a straight image line constituted by a first contour line and a second contour line. The gravure printing plate includes a cell group including a reference cell for printing the first contour line, and image line composition cells present in a projection portion in which the reference cell is projected up to the second contour line in a direction orthogonal to the first contour line. The dimension of each cell of the reference cell and the image line composition cells in the same cell group in an extension direction of the first contour line is within ±5% of an arithmetic average value of the reference cell and the image line composition cells in the same cell group.

### TECHNICAL FIELD

The present invention relates to a gravure printing plate.

### BACKGROUND ART

Conventionally, gravure printing has been used for various applications such as circuit printing of electronic components. In recent years, gravure printing has been used to produce circuit patterns for RFID, which are used in systems that read and write data on RFID tags contactlessly using radio waves.

Patent Literature 1 describes a method for manufacturing a ceramic electronic component with a conductor formed by gravure printing of conductive paste. The method includes the steps of: preparing a ceramic green sheet; and gravure printing the conductive paste on the ceramic green sheet so as to form a predetermined figure. The predetermined figure has a first figure portion whose length direction is parallel to a printing direction and a second figure portion whose length direction is orthogonal to the printing direction. The gravure printing uses a gravure printing plate which has a plurality of first cells for printing the first figure portion and a plurality of second cells for printing the second figure portion, in which the shapes of the first cells and the second cells are different.

### CITATION LIST

### Patent Literature

Patent Literature 1: Japanese Patent Application Laid-Open No. 2004-207641

### SUMMARY OF INVENTION

### Technical Problem

However, in the above-mentioned manufacturing method of a ceramic electronic component, the first cells are continuously arranged in the printing direction and the shapes of the cells are not consistent in a line width direction of a linear image line. Also, the cell widths of the second cells are not consistent in the line width direction of the linear image line. Therefore, there is a problem where ink filled in the cells cannot be transferred stably to a printed member, which may lead to a printing defect such as blank sections.

The present invention provides a gravure printing plate that can transfer an ink filled in cells to a printed object with stability.

### Solution to Problem

A gravure printing plate according to the present invention is a gravure printing plate for printing an image line including a straight image line constituted by a first contour line and a second contour line, the gravure printing plate including

a cell group including
a reference cell for printing the first contour line, and
one or more image line composition cells present in a projection portion in which the reference cell is projected up to the second contour line in a direction orthogonal to the first contour line, wherein

a dimension of each cell of the reference cell and the image line composition cells constituting the same cell group in an extension direction of the first contour line is within ±5% of an arithmetic average value of the reference cell and the image line composition cells constituting the same cell group, and

a dimension of each cell of the reference cell and the image line composition cells constituting the same cell group in a direction orthogonal to the extension direction of the first contour line is within ±5% of an arithmetic average value of the reference cell and the image line composition cells constituting the same cell group.

### Advantageous Effects of Invention

The gravure printing plate of the present invention can print straight image lines with high accuracy by transferring an ink filled in cells stably to a printed object.

The straight image lines printed on the printed object using the gravure printing plate of the present invention do not have any cut-off part, which is caused by blank sections in the extension direction when printing, and are formed in a continuous series in the extension direction. Therefore, according to the gravure printing plate of the present invention, circuit patterns of electronic components, etching resist patterns (photoresist film) for forming circuit patterns, one-dimensional codes, two-dimensional codes, and the like can be printed with high accuracy.

### BRIEF DESCRIPTION OF DRAWINGS

FIG. 1 is a perspective view illustrating an example of a gravure printing plate.

FIG. 2 is a perspective view illustrating another example of the gravure printing plate.

FIG. 3 is a plan view illustrating an example of a cell.

FIG. 4 is a cross-sectional view illustrating an example of the cell.

FIG. 5 is a development view illustrating formation of cells in the gravure printing plate.

FIG. 6 is a schematic view illustrating an example of a gravure printing apparatus.

FIG. 7 is a photograph of straight image lines applied to a printed object of Practical Example 2.

### DESCRIPTION OF EMBODIMENTS

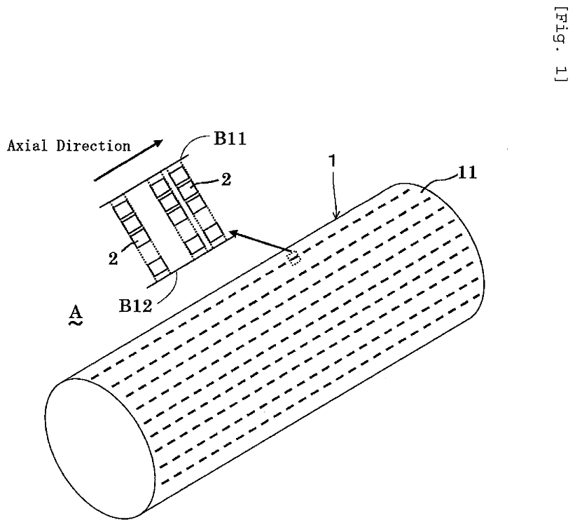

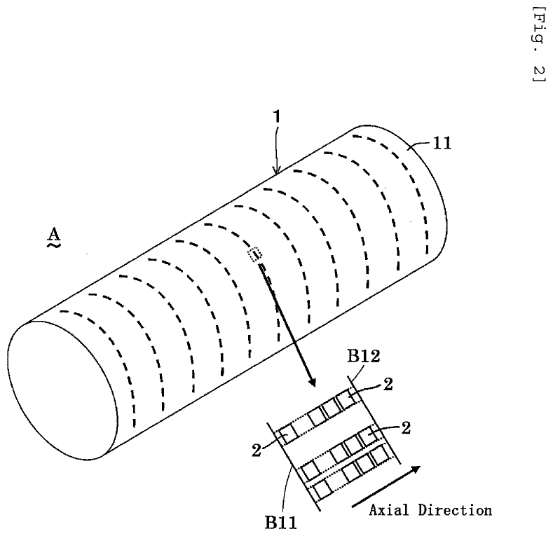

An example of a gravure printing plate of the present invention will be described with reference to the drawings. As illustrated in FIGS. 1 and 2, a gravure printing plate A is constituted by a number of cells 2 that are formed on a peripheral surface of a cylindrical gravure printing plate body 1 in accordance with the shape of image lines to be formed on a printed object.

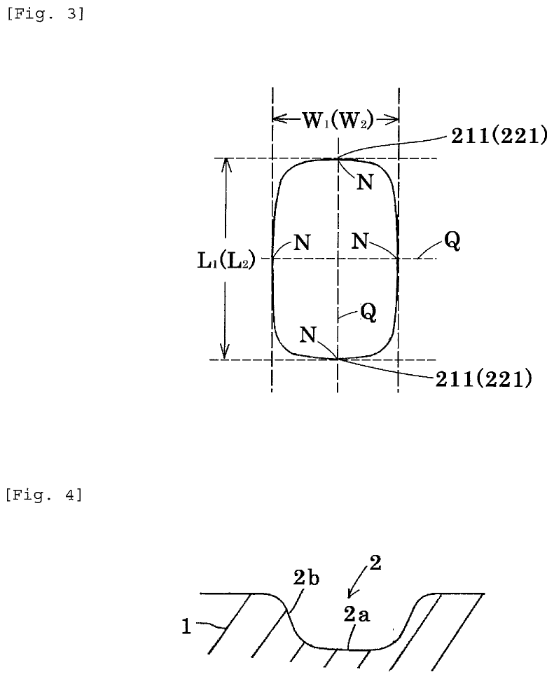

The cells 2 are formed in an entirely open state on a peripheral surface 11 of the gravure printing plate body 1. It is preferable that openings of the cells 2 be formed in a rectangular shape so that an ink filled in the cells 2 can be smoothly transferred to the printed object. As illustrated in FIG. 3, sides constituting an opening end of the cell 2 may each be in the shape of an arc bulging outward. Also, intersections of the sides constituting the opening end of the cell 2 may each be formed in the shape of an arc. Note that, as illustrated in FIG. 4, the cell 2 includes a bottom surface 2a formed in the shape of a concave arc in cross section, and a peripheral wall 2b that gradually expands outward from an outer edge of the bottom surface 2a to the peripheral surface (surface) of the gravure printing plate body 1.

In the case of performing gravure printing using the gravure printing plate A, as described below, the gravure printing plate is dipped into an application liquid pan 4 to fill the cells 2 of the gravure printing plate A with an ink F contained in the application liquid pan 4. After the cells 2 of the gravure printing plate A are filled with the ink F, excess ink F on the outer peripheral surface and cells 2 of the gravure printing plate A is removed with a doctor blade 5.

An edge of a thin plate, called a cutting edge, of the doctor blade is in direct contact with the peripheral surface of the gravure printing plate to remove the excess ink on the peripheral surface and cells of the gravure printing plate. If an opening shape (in particular, size) differs from cell to cell, scraping condition of the ink F by the doctor blade may differ from cell to cell, and transfer condition of the ink F to the printed object may differ from cell to cell. As a result, the amount of the ink F to be transferred becomes uneven from cell to cell, which may cause the ink F to thin or smear and may lead to decreased straightness of contours of straight image lines. Furthermore, when the line width of the straight image lines is narrower, the straight image lines may be broken off.

Image lines B formed on the printed object by the gravure printing plate A only need to include a straight image line B1, and may also include a curved image line B2 which contains curves. The straight image lines B1 each refer to an image line in which a pair of contour lines B11 and B12 constituting the image line are straight and parallel to each other. Of the image lines, image lines excluding the straight image lines B1 are referred to as the curved image lines B2.

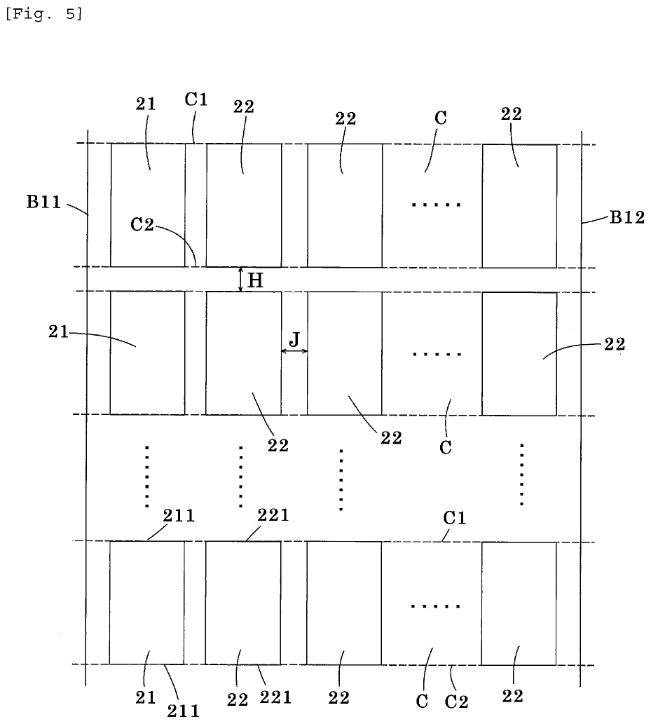

As illustrated in FIG. 5, the gravure printing plate A has cell groups each of which includes a reference cell 21 for printing one of the pair of contour lines B11 and B12 constituting the straight image line B1, i.e. the first contour line B11, and one or more image line composition cells 22 present in a projection portion C in which the reference cell 21 is projected up to the second (other) contour line B12 in a direction orthogonal to the first contour line B11.

Any contour line of the pair of contour lines B11 and B12 constituting the straight image line B1 may be chosen as the first contour line B11 to be used for identifying the reference cell 21. A cell for printing this chosen contour line B11 (cell the ink from which forms a part of the contour line B11 when the filled ink is transferred to the printed object) is designated as the reference cell 21.

The peripheral surface of the gravure printing plate body 1 is developed in a planar shape, and in this developed state, the opening end of the reference cell 21 is projected onto the projection portion C, up to the second contour line B12, in the direction orthogonal to the first contour line B11. One or more cells that are present in the projection portion C are referred to as the image line composition cells 22. The “projection portion C in which the reference cell 21 is projected up to the second (other) contour line B12 in a direction orthogonal to the first contour line B11” refers to a portion enclosed by a pair of projection lines C1 and C2, which are drawn from each of edges 211, 211 of the reference cell 21 in an extension direction (length direction) of the first contour line B11 orthogonally to the first contour line B11, the second contour line B12, and an edge of the opening end of the reference cell 21 that faces the second contour line B12.

Then, the one or more cells that are present within the projection portion C defined as described above are referred to as the image line composition cells 22. A cell that is present within the projection portion C is defined as a cell the opening end of which is present within the projection portion C at more than 50% in area.

The cell group is constituted by the reference cell 21 and the one or more image line composition cells 22. The dimensions of the opening ends of the reference cell 21 and the image line composition cells 22, constituting the cell group, in the extension direction (length direction) of the first contour line B11 are within ±5% of an arithmetic average value of the dimensions of the opening ends of the reference cell 21 and the image line composition cells 22 in the extension direction (length direction) of the contour line B11 [(arithmetic average value×0.95) to (arithmetic average value×1.05)]. In the same cell group, it is preferable that the dimensions of the opening ends of the reference cell 21 and the image line composition cells 22 in the extension direction (length direction) of the first contour line B11 be the same.

Furthermore, the dimensions of the opening ends of the reference cell 21 and the image line composition cells 22, constituting the above-described cell group, in a direction orthogonal to the extension direction (length direction) of the first contour line B11 are within ±5% of an arithmetic average value of the dimensions of the opening ends of the reference cell 21 and the image line composition cells 22 in the direction orthogonal to the extension direction (length direction) of the contour line B11 [(arithmetic average value×0.95) to (arithmetic average value×1.05)]. In the same cell group, it is preferable that the dimensions of the opening ends of the reference cell 21 and the image line composition cells 22 in the direction orthogonal to the extension direction (length direction) of the first contour line B11 be the same.

As described above, the dimensions of the opening ends of the reference cell 21 and the image line composition cells 22, constituting the cell group, in the extension direction of the first contour line B11 and the direction orthogonal thereto are formed in approximately the same dimensions, so that the opening shape of the cells can be made approximately uniform.

Therefore, it is possible to suppress non-uniformity in the amount of the ink to be transferred from each of the cells 21 and 22, and to thereby print the straight image line with high accuracy.

In the same cell group, it is preferable that there be no cells other than the image line composition cells 22 in the projection portion C formed by projecting the reference cell 21 in the direction orthogonal to the first contour line B11 up to the second contour line B12.

In the same cell group, it is preferable that the entire opening ends of all the image line composition cells 22 be present within the projection portion C. In other words, it is preferable that the opening end of each cell of the image line composition cells 22 be present within the projection portion C without protruding from the projection portion C.

In this way, all the opening ends of the image line composition cells 22 are present within the projection portion C without protruding from the projection portion C, or there are no cells other than the image line composition cells 22 in the projection portion C, which may accomplish even scraping of the ink by the doctor blade and maintain more uniform ink filling density in the cells.

In the same cell group, it is preferable that edges 221 of the opening ends of the image line composition cells 22 in the extension direction (length direction) of the first contour line B11 be positioned on the projection lines C1 and C2. The percentage of the image line composition cells 22, either one of the edges 221 of the opening ends of which in the extension direction (length direction) of the first contour line B11 is positioned directly on the projection line C1 or C2, to total number of the image line composition cells 22 is preferably 50% or more, more preferably 60% or more, more preferably 70% or more, more preferably 80% or more, more preferably 90% or more, and more preferably 100%. The percentage of the image line composition cells 22, both edges 221 of the opening ends of which in the extension direction (length direction) of the first contour line B11 are positioned directly on the projection lines C1 and C2, to the total number of the image line composition cells 22 is preferably 50% or more, more preferably 60% or more, more preferably 70% or more, more preferably 80% or more, more preferably 90% or more, and more preferably 100%.

In the present invention, the dimension of a cell in a predetermined direction (for example, “D direction”) means a maximum value of the distance between intersections N and N of an optional straight line Q extending in the D direction on the cell and an edge of an opening end of the cell. The total length of the straight line Q is inside the edge of the opening end of the cell, and the straight line Q is not in contact with the edge of the opening end except at the intersections N and N.

In a case in which the extension direction of the first contour line B11 is orthogonal to an axial direction of the gravure printing plate, the dimension L₁ of the opening ends of the reference cell 21 and the image line composition cells 22 in the direction of the first contour line B11 is preferably 30 to 480 μm, more preferably 35 to 290 μm, more preferably 35 to 240 μm, and more preferably 40 to 185 μm. When the dimension L₁ is within the above-mentioned range, the ink can be transferred stably to the printed object, and a line in a direction orthogonal to the axial direction of the gravure printing plate (a component of the straight image line) can be reproduced with a consistent width.

In a case in which the extension direction of the first contour line B11 is orthogonal to the axial direction of the gravure printing plate, the dimension W₁ of the opening ends of the reference cell 21 and the image line composition cells 22, in a direction orthogonal to the first contour line B11, is preferably 30 to 230 μm, more preferably 40 to 228 μm, and more preferably 50 to 225 μm. When the dimension W₁ is within the above-mentioned range, the ink can be transferred stably to the printed object, and the straight image line can be printed with high accuracy.

In a case in which the extension direction of the first contour line B11 is parallel to the axial direction of the gravure printing plate, the dimension L₂ of the opening ends of the reference cell 21 and the image line composition cells 22, in the direction of the first contour line B11, is preferably 30 to 590 μm, more preferably 35 to 450 μm, more preferably 40 to 400 μm, and more preferably 50 to 180 μm. When the dimension L₂ is within the above-mentioned range, the ink can be transferred stably to the printed object, and the straight image line can be printed with high accuracy.

In a case in which the extension direction of the first contour line B11 is parallel to the axial direction of the gravure printing plate, the dimension W₂ of the opening ends of the reference cell 21 and the image line composition cells 22, in the direction orthogonal to the first contour line B11, is preferably 30 to 230 μm, more preferably 45 to 200 μm, and more preferably 60 to 140 μm. When the dimension W₂ is within the above-mentioned range, the ink can be transferred stably to the printed object, and the straight image line can be printed with high accuracy.

A maximum depth G of the reference cell 21 and the image line composition cells 22 is preferably 5 to 50 μm, more preferably 10 to 45 μm, more preferably 20 to 35 μm, and more preferably 23 to 33 μm. The maximum depth G of the reference cell 21 and the image line composition cells 22 refers to a maximum value of a distance from the peripheral surface of the gravure printing plate body 1 before forming the cell to the bottom surface 2a of the cell in a direction orthogonal to the peripheral surface.

In a case in which the extension direction of the first contour line B11 is orthogonal to the axial direction of the gravure printing plate, the distance J between adjacent cells of the reference cell 21 and the image line composition cells 22 constituting the same cell group is preferably 1 to 30 μm, more preferably 3 to 25 μm, and more preferably 5 to 20 μm. Every distance J between the cells adjacent to each other in the same cell group is preferably within ±10% of an arithmetic average value of the distances J between the cells present in the same cell group, and more preferably within ±5% of the arithmetic average value of the distances J between the cells present in the same cell group. When the distance J between the cells is within the above-mentioned range, the ink can be transferred stably to the printed object, and the straight image line can be printed with high accuracy.

In a case in which the extension direction of the first contour line B11 is parallel to the axial direction of the gravure printing plate, the distance J between adjacent cells of the reference cell 21 and the image line composition cells 22 constituting the same cell group is preferably 1 to 30 μm, more preferably 3 to 25 μm, and more preferably 5 to 20 μm. Every distance J between the cells adjacent to each other in the same cell group is preferably within ±10% of an arithmetic average value of the distances J between the cells present in the same cell group [(arithmetic average value×0.9) to (arithmetic average value×1.1], and more preferably within ±5% of the arithmetic average value of the distances J between the cells present in the same cell group [(arithmetic average value×0.95) to (arithmetic average value×1.05)].

Note that the distance J between the cells adjacent to each other refers to the shortest distance between the edges of the opening ends of the cells adjacent to each other in the direction orthogonal to the first contour line B11.

In a case in which the extension direction of the first contour line B11 is orthogonal to the axial direction of the gravure printing plate, the distance between the cell groups adjacent to each other in the extension direction (length direction) of the first contour line B11 is preferably 1 to 30 μm, more preferably 3 to 25 μm, and more preferably 5 to 20 μm.

In a case in which the extension direction of the first contour line B11 is parallel to the axial direction of the gravure printing plate, the distance between the cell groups adjacent to each other in the extension direction (length direction) of the first contour line B11 is preferably 1 to 30 μm, more preferably 3 to 25 μm, and particularly preferably 5 to 20 μm.

The distance H between the cell groups refers to, in the cell groups adjacent to each other, the distance between a projection line C1 that is set in one of the cell groups and which faces the other cell group and another projection line C1 that is set in the other cell group and which faces the one cell group.

The number of the image line composition cells 22 disposed between the first and second contour lines B11 and B12 is not specifically limited, and may be adjusted as appropriate according to the distance between the first and second contour lines B11 and B12 (width of the straight image line).

It is preferable to divide the area between the first and second contour lines B11 and B12 into a desired number of compartments (preferably equally spaced) with virtual lines parallel to the contour lines B11 and B12, and to form one reference cell 21 or image line composition cell 22 in each compartment.

In a case in which the area between the first contour line B11 and the second contour line B12 is divided into two compartments, the reference cell is formed in the compartment on the side of the first contour line B11, and one image line composition cell 22 is formed in the compartment on the side of the second contour line B12.

In a case in which the area between the first contour line B11 and the second contour line B12 is divided into three or more compartments, the reference cell 21 is formed in the compartment formed by the first contour line B11 and the virtual straight line adjacent thereto, and one image line composition cell 22 is formed in each of the remaining compartments.

In this way, the gravure printing plate A can print the straight image line with high accuracy because the reference cells 21 and the image line composition cells 22 are formed under these specified conditions.

Next, a method for manufacturing the gravure printing plate A will be described. The gravure printing plate A can be manufactured by a known manufacturing method.

The above-mentioned gravure printing plate body 1 is generally formed of metal such as iron or aluminum, and is applied with a plating layer (surface layer) formed of copper or another material on a surface. The gravure printing plate A can then be manufactured by forming the cells on a surface of the plating layer of the gravure printing plate body 1 using a chemical or mechanical method. After the cells 2 are formed on the plating layer of the gravure printing plate body 1, chrome plating or the like may be applied to the surface of the plating layer.

As a chemical method for forming the cells, the surface of the plating layer of the gravure printing plate body 1 is polished to a mirror-like surface, and then a photosensitive agent is applied to the surface of the plating layer (surface layer). After the photosensitive agent is cured so as to form a negative type of cell pattern (dot pattern), the uncured photosensitive agent is removed. The plating layer that is not covered with the photosensitive agent can be corroded by a corrosive solution to depress the plating layer and form the cells.

As a mechanical method for forming the cells, for example, after the plating layer (surface layer) of the gravure printing plate body 1 is polished to a mirror-like surface, the cells can be formed by carving and depressing the surface of the plating layer with a diamond needle called a stylus.

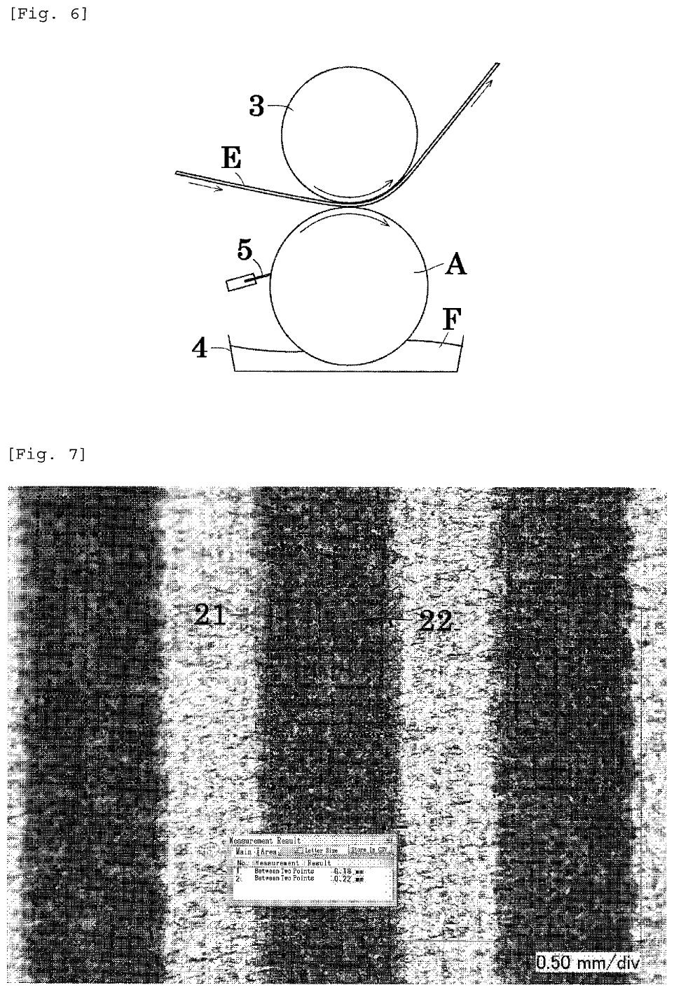

A procedure for printing on a printed object using the gravure printing plate A will be described. First, a gravure printing apparatus used in a gravure printing method will be described. In FIG. 6, the application liquid pan 4 for storing the ink F is disposed under the gravure printing plate A. Note that, the doctor blade 5 is disposed at a side of the gravure printing plate A to remove excess ink from the peripheral surface and cells of the gravure printing plate A.

In addition, a backup roll 3 is disposed over the gravure printing plate A so that printed objects E fed between opposite surfaces of the gravure printing plate A and the backup roll 3 are sequentially pressed. The feeding speed of the printed object E is preferably 20 to 150 m/min, more preferably 30 to 100 m/min, and particularly preferably 40 to 60 m/min. Note that the printed object E can be anything that can be printed by gravure printing, and examples of the printed object E include metal foil, a synthetic resin sheet, paper, and a laminated sheet thereof.

Furthermore, the ink F is supplied into the application liquid pan 4. A lower part of the gravure printing plate A is immersed in the ink F in the application liquid pan 4. The gravure printing plate A is rotated clockwise in FIG. 6, and the doctor blade 5 removes the excess ink F from the peripheral surface and cells of the gravure printing plate A. The rotational speed of the gravure printing plate A is preferably 30 to 300 rpm, more preferably 45 to 200 rpm, and more preferably 60 to 120 rpm. The viscosity of the ink in a Zahn cup #3 is preferably 13 to 40 seconds, more preferably 16 to 35 seconds, more preferably 18 to 30 seconds, and more preferably 19 to 25 seconds.

The formation of the cells of the gravure printing plate A as described above prevents the ink filled in the cells from being scraped unevenly or having an uneven ink filling density when the excess ink F on the peripheral surface and cells of the gravure printing plate A is removed by the doctor blade 5. Therefore, the desired amount of ink can be transferred from the cells of the gravure printing plate A to the printed object with high accuracy, which may lead to printing of the straight image line with high accuracy.

Then, after the ink filled in the reference cell 21 and the image line composition cells 22 of the gravure printing plate A is transferred onto the printed object E, the ink is dried to provide a desired printing form.

Printing forms that can be gravure printed using the gravure printing plate A are not particularly limited. However, the printing forms that require high printing accuracy, such as etching resist patterns for manufacturing circuit patterns for RFID tags and electronic circuit patterns for electronic components, one-dimensional codes such as barcodes, and two-dimensional codes such as QR codes (registered trademark), are preferred.

In a case in which the printing form on the printed object E is an etching resist pattern, the printed object E to which gravure printing is applied is a laminated sheet of a synthetic resin sheet and metal foil, and a desired form of printing is applied on the metal foil. A desired circuit pattern can be fabricated by applying etching process to the metal foil of the laminated sheet using an etching solution to dissolve and remove an unnecessary part of the metal foil (a part where the etching resist pattern is not applied). Note that conventionally known etching solutions can be used, and examples of the etching solution include hydrochloric acid, nitric acid, and iron(III) chloride.

The above describes a case in which the extension direction (length direction) of the first contour line B11 and the second contour line B12 constituting the straight image line is parallel or orthogonal to the axial direction of rotation of the gravure printing plate. However, the present invention is not limited to this, and may be similarly applied to a case in which the first contour line B11 and the second contour line B12 intersect with the axial direction of rotation of the gravure printing plate.

### Experimental Example

Experiment was conducted to identify an appropriate opening shape of cells for the present invention. The experiment will be described below. Gravure printing was performed using the gravure printing apparatus illustrated in FIG. 6. First, a long base material sheet S in which a polyester film with a thickness of 38 μm and aluminum foil with a thickness of 10 μm were laminated and integrated by intermediary of a polyurethane adhesive was prepared as the printed object.

A resist ink (Viscosity in Zahn cup #3: 22 seconds) was made in which 10 parts by weight of a pigment and 30 parts by weight of an acrylic resin were dissolved in an organic solvent containing 10 parts by weight of toluene, 10 parts by weight of ethyl acetate, 10 parts by weight of butyl acetate, 20 parts by weight of isopropyl alcohol, and 10 parts by weight of methyl ethyl ketone.

Then, the Swedish steel doctor blade 5 (manufactured by Rolf Meyer) having a polished cutting edge with a thickness of 60 μm, a hardness of HV580, and a width of 1250 mm was prepared.

The gravure printing plate A with a width (length) of 1100 mm was prepared. In the surface of the gravure printing plate A, the reference cells 21 and the image line composition cells 22 were formed to print the straight image lines constituted by the first and second contour lines extending in directions shown in Tables 1 and 2 and parallel to each other, and the reference cells 21 and the image line composition cells 22 constituted cell groups. This experiment was conducted by printing a straight image line element with one end constituting the first contour line B11 and another end (the other end) constituting the second contour line B12, using the single cell group (cell group in which the reference cell 21 and the image line composition cells 22 are aligned in a single row). The image line composition cells 22 were entirely present within the projection portion C without protruding from the projection portion C. In Tables 1 and 2, “axial direction” indicates a case in which the first and second contour lines extend in the axial direction of a rotational axis of the gravure printing plate A, and “orthogonal direction” indicates a case in which the first and second contour lines extend in a direction orthogonal to the axial direction of the rotational axis of the gravure printing plate A.

The reference cell 21 and the image line composition cells 22 each included the bottom surface 2a formed in the shape of a concave arc in cross section and the peripheral wall 2b that gradually expanded outward from the outer edge of the bottom surface 2a to the peripheral surface (surface) of the gravure printing plate body 1, as illustrated in FIG. 4.

As for the opening ends of the reference cell 21 and the image line composition cells 22, Tables 1 and 2 show the dimension L₁ or L₂ of the opening ends in the extension direction (length direction) of the first contour line B11 and the dimension W₁ or W₂ of the opening ends in the direction orthogonal to the extension direction (length direction) of the first contour line B11. Tables 1 and 2 show the maximum depth G of the reference cell 21 and the image line composition cells 22. As illustrated in FIG. 3, the opening end of each of the reference cell 21 and the image line composition cells 22 was formed in a rectangular planar shape, each side was formed in an outwardly bulging arc and each vertex was also formed in an arc. In each of Experimental Examples 1 to 24, the opening ends of the reference cell 21 and the image line composition cells 22 all had the same shape and size, and the above-mentioned dimensions L₁ (L₂) and W₁ (W₂) and the maximum depth G were all the same.

Both the edges 221 and 221 of the image line composition cells 22 in the extension direction of the first contour line B11 were all positioned on the projection lines C1 and C2.

Tables 1 and 2 show the distance J between the cells adjacent to each other in the same cell group. In each of Experimental Examples 1 to 24, the distance J between the cells adjacent to each other was all the same in the same cell group.

The above-mentioned gravure printing plate A was used, and the lower part of the gravure printing plate A was immersed in the resist ink F supplied into the application liquid pan 4. Next, the gravure printing plate A was rotated clockwise in FIG. 6 at a constant rotational speed shown in Tables 1 and 2 around its axis, and at the same time, the doctor blade 5 was brought into contact with the peripheral surface of the gravure printing plate A with its cutting edge pressed against the peripheral surface of the gravure printing plate A, and the doctor blade 5 was reciprocated left and right in the axial direction of the rotational axis of the gravure printing plate A (in a width direction of the gravure printing plate).

Next, the long base material sheet S was continuously fed between the opposite surfaces of the gravure printing plate A and the backup roll 3 at a feeding speed of 50 m/min. By pressing the base material sheet S from both sides by the gravure printing plate A and the backup roll 3, the resist ink F filled in the reference cell 21 and the image line composition cells 22 of the gravure printing plate A was transferred and applied to a surface of the aluminum foil of the base material sheet S to print a straight image line element.

After that, the base material sheet S was supplied to a hot air drying oven. The hot air drying oven included a first drying section maintained at 120° C., a second drying section continuously connected to a downstream side of the first drying section and maintained at 140° C., and a third drying section continuously connected to a downstream side of the second drying section and maintained at 160° C. The base material sheet S was sequentially fed into the first, second, and third drying sections, and dried for 3 seconds in each drying section to dry the resist ink and form the straight image line element with a length of 1 to 15 μm.

The printing result obtained as described above was magnified 300 times using a microscope to take a magnified photograph, and a line width difference X was calculated by subtracting a minimum value from a maximum value of a line width of the image line element. As shown in Tables 1 and 2, good printing results with small line width differences X were obtained. It can be expected to reproduce a straight image line by arranging a plurality of image line elements between the first contour line B11 and the second contour line B12 in the direction orthogonal to the first contour line B11.

TABLE 1

| | | Experimental Example | | | | | | | | | | | | |
|---|---|---|---|---|---|---|---|---|---|---|---|---|---|---|
| | | 1 | 2 | 3 | 4 | 5 | 6 | 7 | 8 | 9 | 10 | 11 | 12 | 13 |
| Direction of First and | | Orthog- | Orthog- | Orthog- | Orthog- | Orthog- | Orthog- | Orthog- | Orthog- | Orthog- | Orthog- | Orthog- | Orthog- | Orthog- |
| Second Contour Lines | | onal | onal | onal | onal | onal | onal | onal | onal | onal | onal | onal | onal | onal |
| | | Direc- | Direc- | Direc- | Direc- | Direc- | Direc- | Direc- | Direc- | Direc- | Direc- | Direc- | Direc- | Direc- |
| | | tion | tion | tion | tion | tion | tion | tion | tion | tion | tion | tion | tion | tion |
| Cell | Dimension | 100 | 35 | 65 | 95 | 185 | 235 | 40 | 240 | 290 | 80 | 120 | 170 | 220 |
| | L₁(μm) | | | | | | | | | | | | | |
| | Dimension | 50 | 65 | 55 | 65 | 65 | 125 | 60 | 80 | 130 | 100 | 60 | 60 | 80 |
| | W₁(μm) | | | | | | | | | | | | | |
| | Maximum Depth | 25 | 25 | 25 | 25 | 25 | 25 | 30 | 30 | 30 | 25 | 25 | 25 | 25 |
| | G (μm) | | | | | | | | | | | | | |
| | Distance between | 15 | 15 | 15 | 15 | 15 | 15 | 10 | 10 | 10 | 30 | 30 | 30 | 30 |
| | Cells J (μm) | | | | | | | | | | | | | |

| | | | | | | | | | | | | | |
|---|---|---|---|---|---|---|---|---|---|---|---|---|---|
| Rotational Speed (rpm) | 82.6 | 78.7 | 78.7 | 78.7 | 78.7 | 78.7 | 78.7 | 78.7 | 78.7 | 78.7 | 78.7 | 78.7 | 78.7 |
| Line Width | 50 | 60 | 40 | 30 | 30 | 80 | 50 | 80 | 90 | 40 | 50 | 40 | 50 |
| Difference X (μm) | | | | | | | | | | | | | |

TABLE 2

| | | Experimental Example | | | | | | | | |
|---|---|---|---|---|---|---|---|---|---|---|
| | | 14 | 15 | 16 | 17 | 18 | 19 | 20 | 21 | 22 |
| Direction of First and | | Axial | Axial | Axial | Axial | Axial | Axial | Axial | Axial | Axial |
| Second Contour Lines | | Direction | Direction | Direction | Direction | Direction | Direction | Direction | Direction | Direction |
| Cell | Dimension L₂(μm) | 100 | 70 | 70 | 70 | 100 | 50 | 180 | 50 | 50 |
| | Dimension W₂(μm) | 140 | 80 | 140 | 110 | 60 | 100 | 130 | 80 | 130 |
| | Maximum Depth G (μm) | 25 | 25 | 25 | 25 | 30 | 30 | 30 | 30 | 30 |
| | Distance between | 15 | 15 | 15 | 15 | 10 | 20 | 20 | 30 | 30 |
| | Cells J (μm) | | | | | | | | | |

| | | | | | | | | | |
|---|---|---|---|---|---|---|---|---|---|
| Rotational Speed (rpm) | 82.6 | 82.6 | 82.6 | 82.6 | 78.7 | 78.7 | 78.7 | 78.7 | 78.7 |
| Line Width | 60 | 50 | 40 | 50 | 50 | 50 | 40 | 60 | 90 |
| Difference X (μm) | | | | | | | | | |

### Practical Examples

The above describes the results of the experiment in which the image line element was printed using the single cell group (cell group in which the reference cell 21 and the image line composition cells 22 are aligned in a straight row). Next, it was confirmed by the following experiment that a straight image line could be printed with high accuracy by arranging a plurality of cell groups in the direction of the first contour line B11.

TABLE 3

| | | Practical Example | | |
|---|---|---|---|---|
| | | 1 | 2 | 3 |
| Direction of First and Second Contour Lines | | Orthogonal Direction | Orthogonal Direction | Orthogonal Direction |
| Total Number of Reference Cell and Image Line Composition Cells | | 2 | 2 | 2 |
| Cell | Dimension L₁(μm) | 70 | 70 | 70 |
| | Dimension W₁(μm) | 50 | 85 | 110 |
| | Maximum Depth G (μm) | 25 | 25 | 25 |
| | Distance between Cells J (μm) | 15 | 15 | 15 |
| | Distance between Cell Groups H (μm) | 15 | 15 | 15 |

| | | | |
|---|---|---|---|
| Rotational Speed (rpm) | 82.6 | 82.6 | 82.6 |
| Line Width Difference Y (μm) | 60 | 40 | 60 |

TABLE 4

| | | Practical Example | | | | | |
|---|---|---|---|---|---|---|---|
| | | 4 | 5 | 6 | 7 | 8 | 9 |
| Direction of First and | | Axial | Axial | Axial | Axial | Axial | Axial |
| Second Contour Lines | | Direction | Direction | Direction | Direction | Direction | Direction |
| Total Number of Reference Cell and | | 2 | 2 | 2 | 2 | 2 | 2 |
| Image Line Composition Cells | | | | | | | |
| Cell | Dimension L₂(μm) | 70 | 70 | 70 | 70 | 70 | 70 |
| | Dimension W₂(μm) | 50 | 80 | 110 | 60 | 70 | 100 |
| | Maximum Depth G (μm) | 25 | 25 | 25 | 25 | 25 | 25 |
| | Distance between | 15 | 15 | 15 | 15 | 15 | 15 |
| | Cells J (μm) | | | | | | |
| | Distance between | 15 | 15 | 15 | 15 | 15 | 15 |
| | Cell Groups H (μm) | | | | | | |

| | | | | | | |
|---|---|---|---|---|---|---|
| Rotational Speed (rpm) | 82.6 | 82.6 | 82.6 | 82.6 | 82.6 | 82.6 |
| Line Width | 70 | 50 | 50 | 50 | 60 | 60 |
| Difference Y (μm) | | | | | | |

Tables 3 and 4 show printing results of Practical Examples 1 to 9 printed in the same manner as described above using a gravure plate in which cell groups, each constituted by one reference cell 21 and one image line composition cell 22, are arranged in the direction of the first contour line B11. In each of Practical Examples 1 to 9, the distance H between the cell groups was constant. As the distance H between the cell groups, the distance J (Tables 1 and 2) at which the image line element could be favorably printed in the experiment described above was adopted.

The printing result obtained as described above was magnified 300 times using a microscope to take a magnified photograph, and a line width difference Y was calculated by subtracting a minimum value from a maximum value of the line width of straight image line. FIG. 7 represents a photograph of linear image lines printed on the printed object in Practical Example 2 of Table 4. On the photograph of FIG. 7, the reference cells 21 and the image line composition cells 22 corresponding to the linear image lines are indicated by dotted lines. As illustrated in FIG. 7 and shown in Tables 3 and 4, straight image lines with small line width differences Y could be printed with high accuracy. In addition, there was no occurrence of a defect (blank sections) in which the inside of the straight image lines was missing.

The distance H between the cell groups in a case in which the extension direction of the first contour line B11 is orthogonal to the axial direction of the gravure printing plate should be similarly set to the distance J between the cells in a case in which the extension direction of the first contour line B11 is the axial direction of the gravure printing plate. The distance H between the cell groups in a case in which the extension direction of the first contour line B11 is the axial direction of the gravure printing plate should be similarly set to the distance J between the cells in a case in which the extension direction of the first contour line B11 is orthogonal to the axial direction of the gravure printing plate.

### CROSS-REFERENCE TO RELATED APPLICATION

The present application claims the priority under Japanese Patent Application No. 2019-235319, filed on Dec. 25, 2019, the disclosure of which is hereby incorporated in its entirety by reference.

### INDUSTRIAL APPLICABILITY

The gravure printing plate of the present invention can print straight image lines with high accuracy by transferring an ink filled in cells stably to a printed object. Therefore, the gravure printing plate of the present invention can print circuit patterns of electronic components, etching resist patterns (photoresist film) for forming circuit patterns, one-dimensional codes, two-dimensional codes, and the like with high accuracy.

### REFERENCE SIGNS LIST

1 gravure printing plate body
2 cell
21 reference cell
22 image line composition cell
3 backup roll
4 application liquid pan
5 doctor blade
A gravure printing plate
B image line
B1 straight image line
B11 first contour line
B12 second contour line
B2 curved image line
C projection portion
C1 projection line
E printed object
F ink

1. A gravure printing plate for printing an image line including a straight image line constituted by a first contour line and a second contour line, the gravure printing plate comprising
a cell group including
a reference cell for printing the first contour line, and
one or more image line composition cells present in a projection portion in which the reference cell is projected up to the second contour line in a direction orthogonal to the first contour line, wherein
a dimension of each cell of the reference cell and the image line composition cells constituting a same cell group in an extension direction of the first contour line is within ±5% of an arithmetic average value of the reference cell and the image line composition cells constituting the same cell group, and
a dimension of each cell of the reference cell and the image line composition cells constituting the same cell group in a direction orthogonal to the extension direction of the first contour line is within ±5% of an arithmetic average value of the reference cell and the image line composition cells constituting the same cell group.

2. The gravure printing plate according to claim 1, wherein dimensions of the reference cell and the image line composition cells constituting the same cell group in the extension direction of the first contour line are the same, and dimensions of the reference cell and the image line composition cells constituting the same cell group in a direction orthogonal to the extension direction of the first contour line are the same.
